(19) United States
(12) Patent Application Publication
(10) Pub. No.: US 2012/0017969 A1
(43) Pub. Date: Jan. 26, 2012

(54) SOLAR CELL DEVICE AND SOLAR CELL DEVICE MANUFACTURING METHOD

(75) Inventor: Shigenori Yuuya, Ashigarakami-gun (JP)

(73) Assignee: FUJIFILM CORPORATION, Tokyo (JP)

(21) Appl. No.: 13/262,576

(22) PCT Filed: Mar. 29, 2010
(86) PCT No.: PCT/JP2010/056111

§ 371 Date: Sep. 30, 2011

(30) Foreign Application Priority Data
Mar. 30, 2009 (JP) 2009-083151
Nov. 11, 2009 (JP) 2009-257808

(51) Int. Cl. H01L 31/042; H01L 31/0224; H01L 31/0256; H01L 31/02

(52) U.S. Cl. 136/244; 136/252; 136/256; 438/93; 257/E31.003

(57) ABSTRACT

A solar cell device is formed of an insulating layer provided metal substrate and a photoelectric conversion circuit, which includes a photoelectric conversion layer, an upper electrode, and a lower electrode, formed on the substrate. The substrate is constituted by a metal substrate and a porous Al anodized film. The metal substrate is formed of a base material of a metal having a higher rigidity, a high heat resistance, and a smaller linear thermal expansion coefficient than Al and an Al material integrated by pressure bonding to at least one surface thereof, and the porous Al anodized film is formed on a surface of the Al material.

### TECHNICAL FIELD

The present invention relates to a solar cell device having an insulating layer provided metal substrate in which an Al anodized film is used as the insulating layer. The invention also relates to a method of manufacturing the solar cell device.

### BACKGROUND ART

Most of conventional solar cells are Si-based cells that use bulk monocrystalline Si, polycrystalline Si, or thin film amorphous Si. Recently, however, research and development of compound semiconductor-based solar cells that do not depend on Si has been carried out. Two types of compound semiconductor-based solar cells are known, one of which is a bulk system, such as GaAs system and the like, and the other of which is a thin film system, such as CIS (Cu—In—Se) system formed of a group Ib element, a group IIIb element, and a group VIb element, CIGS (Cu—In—Ga—Se), or the like. The CIS system or CIGS system has a high light absorption rate, and a high energy conversion efficiency is reported. The film forming temperature of amorphous Si is about 200 to 300° C., but in order to form a favorable compound semiconductor layer having high photoelectric conversion efficiency, the film forming temperature needs to be 500° C. or more.

Currently, glass substrates are mainly used as the substrates of solar cells, but the study for possible use of flexible metal substrates has been going on. Solar cells with a metal substrate have a potential prospect to be applied to a wider range of applications in comparison with those that employ a glass substrate due to lightweight and flexibility of the substrate. Further, it is expected that photoelectric conversion characteristics and hence photoelectric conversion efficiency of solar cells will be improved because the metal substrate can withstand a high temperature process. When using a metal substrate, however, it is necessary to provide an insulating film on the surface of the substrate to prevent short circuiting between the substrate and an electrode or a photoelectric conversion layer formed thereon.

Japanese Unexamined Patent Publication No. 2001-339081 proposes the use of a stainless-steel substrate, as a solar cell substrate, in which an insulating layer is formed thereon by coating a Si or Al oxide by a vapor phase method, such as CVD (chemical vapor deposition) or the like, or a liquid phase method, such as sol gel method or the like. These methods for forming insulating films, however, are likely to produce pin holes or cracks by nature, thus having a fundamental problem as the method for stably producing large thin film insulating layers.

Japanese Unexamined Patent Publication No. 2000-049372 proposes the use of an insulating layer provided metal substrate, as a solar cell substrate, which is an Al (aluminum) substrate with an insulating layer of an anodized film provided by anodizing a surface of the Al substrate. Such method allows, even when a large substrate is used, an insulating film to be formed easily without any pinhole over the entire surface of the substrate.

As described in “Heat-induced cracking of anodic oxide films on aluminum—An in suit measurement of the cracking temperature—”, M. Kayashima and M. Mushiro, Tokyo Metropolitan Industrial Technology Research Institute, Study Report No. 3, pp. 21-24, 2000, it is known that a crack is generated in an anodized film on an Al substrate if heated to 120° C. or higher and such crack causes an insulation problem, in particular, a problem of increased leakage current.

In the mean time, as a substrate of a photovoltaic device having a convention amorphous Si layer, Japanese Unexamined Patent Publication No. 62(1987)-089369 proposes the use of an insulating layer provided metal substrate, which is provided by forming an Al layer on an alloy steel plate and forming an insulating layer on the surface of the Al layer by an anodizing process. Japanese Unexamined Patent Publication No. 62(1987)-089369 describes that the provision of alloy steel plate as the base material may maintain required mechanical strength, such as elastic force and the like, because the alloy steel plate is not softened even when the Al layer is softened by subjected to a temperature of 200 to 300° C. during a deposition process of amorphous Si or the like.

It is believed that the cause of a crack in an anodized film on an Al material is because of a larger liner thermal expansion coefficient of Al (23×10⁻⁶/° C.) than that of an anodized film. That is, although the precise value of the linear thermal expansion coefficient of the anodized film is not known, the value is thought to be close to that of an aluminum oxide (α-alumina) which is about 7×10⁻⁶/° C. Thus, there exists a large difference in liner thermal expansion coefficient of about 16×10⁻⁶/° C. between them, whereby a large unbearable stress is generated in the anodized film and the crack described above might be generated.

Further, Al is softened at a temperature of about 200° C., thus Al subjected to the temperature becomes extremely weak and prone to have a permanent deformation (plastic deformation), such as a creep deformation or a buckling deformation. Accordingly, when such Al is used, it is necessary that the structure of a semiconductor device and handling thereof at the time of manufacturing are strictly restricted. This makes it difficult to apply semiconductor devices to outdoor solar cells.

Japanese Unexamined Patent Publication No. 62(1987)-089369 proposes to use a substrate of alloy steel with an Al material formed thereon as a structure that can withstand heating at 200 to 300° C. when manufacturing a device having an amorphous Si as a photoelectric conversion layer (light absorption layer). But, when a compound semiconductor is used as a photoelectric conversion layer, which has been under study, a higher film forming temperature which is generally around 500° C. is required in order to obtain high photoelectric conversion efficiency. Thus, there is a demand for a substrate having a structure that can withstand a high temperature of not less than 500° C.

In the molten aluminum plated steel plate as described in Japanese Unexamined Patent Publication No. 62(1987)-089369, a thick alloy layer is formed between the aluminum and steel, so that it is highly likely that detachment occurs at the interface between the aluminum and steel when a bending force is applied. If the alloy layer is thin, the detachment may be prevented, but it is difficult in the molten aluminum plating to control the thickness of the alloy layer, and it is difficult to obtain a substrate having sufficient flexibility to meet practical use.

The present invention has been developed in view of the circumstances described above and it is an object of the present invention to provide a solar cell device with an insulating layer provided metal substrate having an anodized film capable of maintaining favorable insulating properties and strength even after subjected to a high temperature of not less than 500° C. which is a manufacturing temperature of a compound semiconductor layer having favorable photoelectric conversion efficiency. It is a further object of the present invention to provide a method of manufacturing the solar cell device described above. It is a still further object of the present invention to provide a solar cell device having a substrate that allows manufacturing of a large area modular solar cell device that can be linked to an electric power system in a roll-to-roll fashion.

### DISCLOSURE OF THE INVENTION

A solar cell device of the present invention is a solar cell device having a photoelectric conversion layer of a compound semiconductor, the solar cell device including:

an insulating layer provided metal substrate constituted by a metal substrate and a porous Al anodized film, the metal substrate being formed of a base material of a metal having a higher rigidity, a higher heat resistance, and a smaller linear thermal expansion coefficient than Al and an Al material integrated by pressure bonding to at least one surface of the base material, and the porous Al anodized film being formed, as an electrical insulating layer, on a surface of the Al material of the metal substrate; and

a photoelectric conversion circuit, which includes the photoelectric conversion layer, and upper and lower electrodes disposed respectively on the upper and lower sides of the photoelectric conversion layer, formed on the insulating layer provided metal substrate.

The metal substrate may have a two-layer structure in which an Al material is integrated to only one surface of the base material or a three-layer structure in which an Al material is integrated to each of two surfaces of the base material. Further, when the metal substrate has the three-layer structure, either one or each of the Al materials may have an anodized film.

The term “Al material” as used herein refers to an Al based metal material, and more specifically, refers to a metal material with an Al content of not less than 90% by mass (wt %). The Al material may be pure Al, pure Al with a trace of unavoidable impurity dissolved therein, or an alloy material of Al and another metal element.

The term “linear thermal expansion coefficient” as used herein refers to a linear thermal expansion coefficient of a bulk body.

The term “rigidity” as used herein refers to resistance to dimensional deformation by an external force, and is measured by yield stress or 0.2% proof stress value. The term “heat resistance” as used herein refers to degradation in rigidity at a temperature not less than 300° C. from that at room temperature.

The metal of the base material may be any metal as long as it has a smaller linear thermal expansion coefficient, a higher rigidity, and a higher heat resistance than Al. In particular, a steel material or a Ti material is preferably used. The term “steel material” as used herein refers to a metal material of steel. The term “steel” as used herein refers to a metal with an iron content of 50% by mass or more. That is, the steel includes iron, so called carbon steel which is carbon containing iron, and an iron alloy made by adding chromium, nickel, molybdenum, or the like to iron in order to obtain suitable properties for an intended application in view of linear thermal expansion coefficient and rigidity. The term “Ti material” as used herein refers to a Ti based metal material. Here, the Ti material may be pure Ti or a Ti alloy, such as Ti-6Al-4V, Ti-15V-3Cr-3Al-3Sn, or the like.

Preferably, the base material and Al material are bonded together without heating.

Preferably, in the solar cell device of the present invention, the photoelectric conversion circuit is a circuit formed of a plurality of elements provided by dividing the photoelectric conversion layer by a plurality of grooves and electrically connected in series.

Preferably, in the solar cell device of the present invention, the difference in linear thermal expansion coefficient between the base material and the photoelectric conversion layer is less than 7×10⁻⁶/° C.

Preferably, in the solar cell device of the present invention, the major component of the photoelectric conversion layer is at least one type of compound semiconductor having a chalcopyrite structure. Preferably, in this case, the base material is a carbon steel material, ferritic stainless steel material, or the Ti material, the lower electrode is formed of Mo, and the major component of the photoelectric conversion layer is at least one type of compound semiconductor formed of a group Ib element, a group IIIb element, and a group VIb element. Preferably, in particular, the group Ib element is at least one type of element selected from the group consisting of Cu and Ag, the group IIIb element is at least one type of element selected from the group consisting of Al, Ga, and In, and the group VIb element is at least one type of element selected from the group consisting of S, Se, and Te.

The solar cell device of the present invention may be a solar cell device in which the base material is a carbon steel material, a ferritic stainless steel material, or the Ti material, and the major component of the photoelectric conversion layer is a CdTe compound semiconductor.

The term “major component of the photoelectric conversion layer” as used herein refers to a component included in the photoelectric conversion layer in an amount not less than 75% by mass.

Element group representation herein is based on the short period periodic table. A compound semiconductor formed of a group Ib element, a group IIIb element, and a group VIb element is sometimes represented herein as “group I-III-VI semiconductor” for short. Each of the group Ib element, group IIIb element, and group VI element, which are constituent elements of group I-III-VI semiconductor, may be one or more types of elements.

A solar cell device manufacturing method of the present invention is a method of manufacturing a solar cell device, including the steps of:

providing an insulating layer provided metal substrate constituted by a metal substrate and a porous Al anodized film, the metal substrate being formed of a base material of a metal having a higher rigidity, a high heat resistance, and a smaller linear thermal expansion coefficient than Al and an Al material integrated by pressure bonding to at least one surface of the base material, and the porous Al anodized film being formed, as an electrical insulating layer, on a surface of the Al material of the metal substrate; and

forming a photoelectric conversion layer of a compound semiconductor on the insulating layer provided metal substrate at a film forming temperature of not less than 500° C.

The solar cell device of the present invention includes an insulating layer provided metal substrate constituted by a metal substrate and a porous Al anodized film, the metal substrate being formed of a base material of a metal having a higher rigidity, a high heat resistance, and a smaller linear thermal expansion coefficient than Al and an Al material integrated by pressure bonding to at least one surface of the base material, and the porous Al anodized film being formed on a surface of the Al material of the metal substrate. This may prevent crack generation in the anodized film even in a film forming process of a photoelectric conversion layer of a compound semiconductor on the substrate which accompanies a high temperature (not less than 500° C.), whereby the insulating layer provided metal substrate may maintain high insulating properties. This might be due to that the thermal expansion of Al is restricted by the base material and the thermal expansion of the entire metal substrate is controlled by the thermal expansion properties of the base material, and that the stress of the anodized film arising from the difference in thermal expansion between the base material and anodized film is alleviated by the interposition of the Al material having a small elastic modulus (Young's modulus) between the base material and anodized film.

Further, in the solar cell device of the present invention, a metal having a higher heat resistance than that of Al is used for the insulating layer provided metal substrate, so that the insulating layer provided metal substrate may maintain a high strength even after a compound semiconductor film forming process which is performed at a high temperature of not less than 500° C.

Still further, the metal substrate is formed of a base material and an Al material integrated by pressure bonding, so that the formation of alloy layer between the base material and Al material may be prevented in comparison with a metal substrate formed by molten aluminum plating or the like. Prevention of the alloy layer may prevent detachment between the Al material and base material even when a bending force is applied. Further, the metal substrate can be manufactured easily, the metal substrate can be manufactured at a low cost in comparison with deposition method or aluminum electroplating, and a large-area substrate can be manufactured easily. That is, the use of the metal substrate formed of a base material with an Al material integrated thereto by pressure bonding results in that a large-area, flexible, and mass-productive solar cell device can be obtained.

As described above, the solar cell device of the present invention includes an insulating layer provided metal substrate that maintains high insulation resistance and strength even after subjected to a high temperature not less than 500° C. Therefore, the solar cell device may include a compound semiconductor formed at a high temperature not less than 500° C. and improve the photoelectric conversion efficiency. According to the solar cell device manufacturing method of the present invention, an insulating layer provided metal substrate that maintains high insulation resistance and strength even after subjected to a high temperature not less than 500° C. is used, so that handling constraints and the like during the manufacturing may be reduced. Further, a photoelectric conversion layer of a compound semiconductor is formed on the substrate at a film forming temperature not less than 500° C., so that a solar cell device that includes a photoelectric conversion layer having a high light absorption rate and a high photoelectric conversion efficiency may be manufactured.

### BRIEF DESCRIPTION OF THE DRAWINGS

FIG. 1 is a schematic cross-sectional view of an insulating layer provided metal substrate used for a solar cell device according to an embodiment of the present invention.

FIG. 2 is a schematic cross-sectional view of another insulating layer provided metal substrate, illustrating a design change example.

FIG. 3 is a schematic cross-sectional view of a solar cell device according to an embodiment of the present invention, illustrating a major portion thereof.

FIG. 4 illustrates the relationship between the lattice constant and band gap of compound semiconductors.

FIG. 5 illustrates heat treatment conditions that cause a 10 μm thick alloy layer to be formed in a metal substrate formed of a base material and an Al material integrated together.

### BEST MODE FOR CARRYING OUT THE INVENTION

Hereinafter, embodiments of the present invention will be described with reference to accompanying drawings. It should be appreciated, however, that the invention is not limited to the embodiments. In the drawings, each component is not drawn to scale in order to facilitate visual recognition.

### (Insulating Layer Provided Metal Substrate)

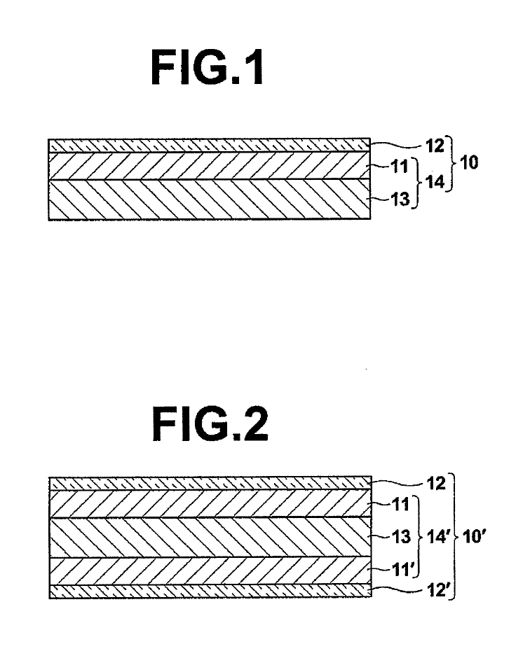

First, an insulating layer provided metal substrate on which a photoelectric conversion circuit is formed in an embodiment of the solar cell device of the invention will be described first. FIG. 1 is a schematic cross-sectional view of an insulating layer provided metal substrate used for a solar cell device of the present invention.

Insulating layer provided metal substrate 10 shown in FIG. 1 includes metal substrate 14 of base material 13 with Al material 11 integrated to one surface of base material 13, and Al anodized film 12 having a porous structure formed on the surface of Al material 11, as an insulating layer, by anodizing the surface of Al material 11. Accordingly, insulating layer provided metal substrate 10 used in the present embodiment has a three-layer structure of base material 13, Al material 11, and anodized film 12.

Metal substrate 14 includes base material 13 of a metal having a smaller linear thermal expansion coefficient, a higher rigidity, and a higher heat resistance than Al with Al material 11 integrated by pressure bonding to one surface thereof.

There is not any specific restriction on the material of base metal 13 and any metal having a smaller linear thermal expansion coefficient, a higher rigidity, and a higher heat resistance than Al may be used. An appropriate metal may be selected according to stress calculation results based on insulating layer provided substrate 10 and the configuration and material properties of a photoelectric conversion circuit provided thereon. In particular, steels or Ti materials are preferable. Examples of preferable steels include austenitic stainless steels (linear thermal expansion coefficient=17×10⁻⁶/° C.), carbon steels (=10.8×10⁻⁶/° C.), ferritic stainless steels (=10.5×10⁻⁶/° C.), 42 invar alloys and kovar alloys (=5×10⁻⁶/° C.), and 36 invar alloys (<1×10⁻⁶/° C.). Examples of preferable Ti materials include pure Ti (=9.2×10⁻⁶/° C.), and wrought alloys of Ti-6Al-4V and Ti-15V-3Cr-3Al-3Sn having a substantially identical linear thermal expansion coefficient.

Although a photoelectric conversion layer formed on an insulating layer provided substrate will be described in detail later, linear thermal expansion coefficients of principal compound semiconductors used as the photoelectric conversion layer are 5.8×10⁻⁶/° C. for GaAs representing group III-V compounds, 4.5×10⁻⁶/° C. for CdTe representing group II-VI compounds, and 10×10⁻⁶/° C. for Cu(InGa)Se₂ representing group I-III-VI compounds. When a compound semiconductor is formed at a high temperature of 500° C. or higher and cooled to room temperature, if the compound semiconductor has a large thermal coefficient difference with the base material, film forming defects, such as detachment of the film and the like, may occur. Further, photoelectric conversion efficiency may be degraded due to a strong internal stress of the compound semiconductor arising from the difference in thermal expansion difference with the base material. Accordingly, it is preferable that the difference in linear thermal expansion coefficient between the base material and compound semiconductor is less than 7×10⁻⁶/° C., and more preferably less than 3×10⁻⁶/° C. Here, the linear thermal expansion coefficients and linear thermal expansion differences are values at room temperature (23° C.).

The thickness of base material 13 may be set arbitrarily based on the handlability (strength and flexibility) of the semiconductor device at the manufacturing process and operation, but is preferable to be 10 μm to 1 mm.

The rigidity of metal substrate 14 is defined by yield stress or 0.2% proof stress since elastic limit stress that does not cause plastic deformation is important. 0.2% proof stress values and their temperature dependencies are described in “Steel Material Handbook”, The Japan Institute of Metals, The Iron and Steel Institute of Japan, Maruzen, Co., Ltd., or “Stainless Steel Handbook (Third Edition)”, Japan Stainless Steel Association, The Nikkan Kogyo Shinbun, Ltd. Although depending on the degree of mechanical processing and thermal refining, the 0.2% proof stress value of base material 13 is preferable to be 250 to 900 MPa at room temperature. When a photoelectric conversion layer is formed on a substrate, the substrate is raised to a high temperature (500° C. or higher), the proof strength of a steel or Ti at 500° C. is generally maintained 70% of the proof strength at room temperature. In the mean time, the proof strength of Al at room temperature is 300 MPa or greater, although depending on the degree of mechanical processing and thermal refining, but decreases to 1/10 of the proof strength of room temperature at 350° C. or higher. Therefore, the elastic limit stress and thermal expansion of insulating layer provided metal substrate 10 at a high temperature are predominantly determined by the high temperature characteristics of base material 13 of steel or Ti. Young's moduli of Al materials and steels or Ti materials and their temperature dependencies required for stress calculations are described in “Elastic Moduli of Metal Materials”, The Japan Society of mechanical Engineers.

The major component of Al material 11 may be pure high-purity Al, Japanese Industrial Standards (JIS) 1000 pure Al, or an alloy of Al with another metal element, such as Al—Mn alloy, Al—Mg alloy, Al—Mn—Mg alloy, Al—Zr alloy, Al—Si alloy, Al—Mg-si, or the like (Aluminum Handbook (in Japanese), 4th edition, Japan Light Metal Association, pp. 1-5 and 219-221, 1990). Al material 11 may include traces of various metal elements, such as Fe, Si, Mn, Cu, Mg, Cr, Zn, Bi, Ni, Ti, and the like in a solid solution state. Preferably, the total amount of components or impurities other than Al in an Al alloy is less than 10 wt %, that is, Al purity is not less than 90 wt % in order to ensure insulating properties of an anodized portion after anodization. In particular, Al purity is more preferable to be not less than 99 wt % in order to prevent leakage current when a high voltage not less than 200 V is applied. Further, an Al material without Si precipitation is desirable in order to ensure insulating properties of an anodized portion after anodization because Si precipitation in the Al material causes the dielectric breakdown voltage to be reduced, thereby increasing the leakage current (Japanese Patent Application No. 2009-113673, not yet laid open at the time of filing the present application).

The thickness of Al material 11 may be selected appropriately according to stress calculation results based on the layer structure of the entire semiconductor device and material properties, but it is preferable to be 0.1 to 500 μm when formed into insulating layer provided metal substrate 10. Interposition of Al material 11 between base material 13 and anodized film 12 may alleviate the stress of anodized film 12 when thermal expansion occurs due to a temperature change. When manufacturing insulating layer provided metal substrate 10, it is necessary to set the thickness of Al material 11 to a value that allows for a lessening amount since the thickness is reduced by anodization and prior washing or polishing.

As described above, metal substrate 14 is formed of base material 13 and Al material 11 integrated together by pressure bonding. Preferably, in particular, the metal substrate is formed of a base material and an Al material bonded together without heating at the time of pressure bonding. Here, the term bonded together without heating as used herein refers to that the materials are bonded together under room temperature without externally applied heat.

As a method of forming a metal substrate by integrating an Al material to a base material, molten plating on a base material is known as described, for example, in Japanese Unexamined Patent Publication No. 62(1987)-089369. But the melting point of aluminum is 660° C., so that Molten plating temperature should generally be not less than 700° C. The inventors of the present invention have confirmed that a thick alloy layer exceeding 10 μm, as well as a void and a crack due to formation of the alloy layer, are formed at the interface between the base material and Al material of the metal substrate subjected to such a high temperature. Presence of the void, crack, or the like at the interface between base material and Al material causes detachment to occur at the interface when a bending force is applied to the substrate, so that a flexible solar cell device can not be obtained. The alloy layer generated at the interface is presumed to be mainly formed of a brittle intermetallic compound.

Further, presence of such a brittle alloy layer and the void or crack due to formation of the alloy layer at the interface between the base material and Al material poses a reliability problem as a solar cell device for not only flexible solar cell devices but also those not flexible, because the elements are repeatedly subjected to heat expansion and contraction due to the heat cycle between the sunlight and nighttime temperature and the crack or the like may trigger breakage or detachment.

Further, the Galvalume steel plate is known as a molten aluminum plated steel plate. It uses aluminum doped with a little over 40 wt % of zinc and several wt % of silicon to lower the melting temperature, thereby preventing the formation of an alloy layer of a base material and the aluminum alloy (aluminum, zinc, and silicon) at the interface between the base material and aluminum alloy. It may be conceivable to use the identical technology, that is, to use an aluminum alloy to lower the melting temperature and to prevent the formation of an alloy layer of a base material and the aluminum alloy at the interface thereof. In order to lower the melting temperature of an aluminum alloy by 100° C. or more from the melting point of 660° C. of pure aluminum, it is necessary, in general, to add an alloy element of not less than 10 wt %. The inventors of the present invention have confirmed that an anodized film obtained by anodizing an aluminum alloy plated layer of an aluminum alloy material that includes a not less than 10 wt % of an alloy element can not satisfy insulating properties required of a modular solar cell device, such as a high withstand voltage, small leakage current, and the like (Examples described later).

On the other hand, with respect to metal substrate 14 formed by integrating base material 13 with Al material 11 by pressure bonding, substantially no alloy layer is formed at the interface between them when it was formed without heating at the time of pressure bonding. Even metal substrate 14 formed only by pressure bonding and rolling, that is, without heating, is inevitably heated when a film, such as semiconductor layer or the like, is formed on the substrate, whereby an alloy layer is formed at the interface between base material 13 and Al material 11. The growth of an alloy layer due to heat treatment will now be described.

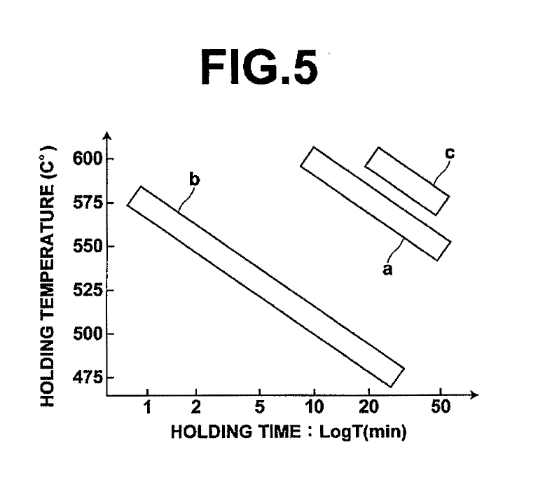

FIG. 5 illustrates, in the form of a TTT diagram (Time-Temperature-Transform Diagram), heat treatment condition that causes an alloy layer, formed at the interface between the base material and Al material when each of metal substrates (clad materials) “a” to “c” obtained by only pressure bonding and rolling without heating is heat treated, to grow to a thickness of 10 μm obtained by the inventors of the present invention.

In FIG. 5, the heat treatment conditions that cause an alloy layer at the interface between the base material and Al material of metal substrates “a” to “c” are indicated by reference symbols “a” to “c”. Each of the heat treatment conditions is represented by a strip-like area in consideration of errors. The base material of metal substrate “a” is a ferrite stainless steel (SUS 430), base material of metal substrate “b” is a low-carbon steel (SPCC), and base material of metal substrate “c” is a high purity Ti material with a purity of 99.5%. The Al material of each of substrates “a” to “c” is high purity (4N) Al.

As shown in FIG. 5, the relationship between the holding temperature and holding time in each heat treatment condition that causes the alloy layer to grow to 10 μm is that the higher the holding temperature the shorter the holding time, that is, the longer the holding time the lower the holding temperature.

With respect to each of substrate “a” to “c”, when the heat treatment condition falls on the lower side and/or left side of the area where the thickness of the alloy layer of the substrate becomes 10 μm in the heat treatment condition shown in FIG. 5, the thickness of the alloy layer of the substrate may be kept less than 10 μm. The alloy layer does not grow uniformly and has a certain irregularity. Therefore, the thickness of an alloy layer herein refers to the average thickness of the alloy layer at a cross-sectional surface of the substrate. The thickness (average thickness) of an alloy layer can be measured by observing a cross-sectional surface of the substrate. More specifically, the thickness of the alloy layer may be obtained by cutting the substrate to expose a cross-sectional surface, photographing the cross-sectional surface with a scanning electron microscope (SEM) or the like, measuring the area of the alloy layer in the photographed image by image analysis, and dividing the area by the length of the field of view.

As shown in FIG. 5, the holding temperature and holding time in the heat treatment condition of each substrate are in a linear relationship, so that the addition rule holds for the growth of an alloy layer at the interface between base material 13 and Al material 11. That is, if the substrate is subjected to a plurality of heat treatment processes, an alloy layer with a thickness which is the total of each thickness grown by the temperature and processing time in each heat treatment process is grown.

Note that FIG. 5 shows only a portion of each heat treatment condition that causes the alloy layer to grow to 10 μm, and according to the study made by the inventors of the present invention, the linear relationship between the holding temperature and holding time may be extended both to higher and lower temperature sides.

As described above, it is evident that a higher heating temperature or a longer heating time in heat treatment of the metal substrate results in a thicker alloy layer. Given the fact that a photoelectric conversion layer is formed on the substrate at a temperature not less than 500° C., metal substrate 14 as a substrate for a solar cell device is, of course, preferable to be the one bonded by pressure bonding without heating. It may be needless to say that it is desirable not to perform metal softening process by heating in the rolling process after pressure bonding.

As for the method of forming the metal substrate, for example, Al deposition on a base material, gas phase method, such as sputtering, or aluminum electroplating using a nonaqueous electrolyte may be conceivable other than the molten plating described above. But, in typical devices used for these methods, it is difficult to make a large-area metal substrate, and it will become very costly to make such a large-area metal substrate. Therefore, a metal substrate of a base material with an Al material integrated thereto by the gas phase method, aluminum electroplating, or the like can not be said to be practical and is not suitable as a substrate for a large-area modular solar cell device that can be linked to an electric power system. As described above, pressure bonding by roller rolling or the like is the most appropriate method for bonding a base material an Al material together from the viewpoint of ease of manufacture of a large-area substrate and also low cost and high mass-productivity.

Anodization may be performed by immersing metal substrate 14, as an anode, together with a cathode in an electrolyte, and applying a voltage between the anode and cathode. Here, when metal base material 13 contacts the electrolyte, a local battery is formed by base material 13 and Al material 11, so that base material 13 contacting the electrolyte needs to be mask insulated. More specifically, in the case of metal substrate 14 having a two-layer structure of base material 13 and Al material 11, it is necessary to insulate the surface of steel base material 13, as well as the end face thereof.

The surface of Al material 11 is cleaned and smoothed by polishing, as required, prior to anodization. As for the cathode, carbon, aluminum, or the like is used. There is not any specific restriction on the electrolyte, and acid electrolytes containing one or more types of acids, such as sulfuric acid, phosphoric acid, chromic acid, oxalic acid, sulfamic acid, benzenesulfonic acid, amido-sulfonic acid, and the like, are preferably used. There is not any specific restriction on the anodizing conditions, which are dependent on the electrolyte used. As for the anodizing conditions, for example, the following are appropriate: electrolyte concentration of 1 to 80% by mass; solution temperature of 5 to 70° C.; current density in the range from 0.005 to 0.60 A/cm²; voltage of 1 to 200 V; and electrolyzing time of 3 to 500 minutes.

At the time of anodization, an oxidization reaction proceeds from the surface in a direction substantially perpendicular to the surface and anodized film 12 is formed on the surface of Al material 11. When an acid electrolyte described above is used, anodized film 12 results in a porous type in which multiple fine columnar bodies, each having a substantially regular hexagonal shape in plan view, are tightly arranged, each having fine pore with a rounded bottom substantially in the center, and a barrier layer is formed (generally, with a thickness of 0.01 to 0.4 μm) at the bottom of fine columnar bodies. Such a porous anodized film has a low Young's modulus in comparison with a non-porous alumina film, resulting in high bend resistance and crack resistance. It is noted that electrolytic treatment using a neutral electrolyte, such as boric acid, instead of an acid electrolyte results in a dense anodized film (non-porous alumina film) instead of an anodized film in which porous fine columnar bodies are disposed. An anodized film having a thicker barrier layer may be formed by first forming a porous anodized film using an acid electrolyte and then performing pore filling in which the porous film is subjected to electrolytic treatment using a neural electrolyte. A thicker barrier layer may result in a film of excellent insulating properties.

There is not any specific restriction on the thickness of anodized film 12 as long as the film has acceptable insulating properties and surface hardness that can prevent damages due to mechanical impact at the time of handling, but a too thick film may cause a flexibility problem. In view of this, a preferable thickness is 0.5 to 50 μm which can be controlled based on the magnitude of current or voltage in constant-current or constant-voltage electrolysis and time of electrolysis.

As described above, a solar cell device of the present invention has an insulating layer provided metal substrate constituted by a metal substrate which includes a base metal material having a small linear thermal expansion coefficient, a higher rigidity, and a higher heat resistance than Al and an Al material integrated by pressure bonding to one surface of the base metal material, and an anodized film formed on the surface of the Al material of the metal substrate. The insulating layer provided metal substrate may prevent crack generation in the anodized film even in a film forming process of a photoelectric conversion layer of a compound semiconductor on the substrate which accompanies a high temperature (not less than 500° C.), whereby high insulating properties may be maintained. This might be due to that the thermal expansion of Al is restricted by the steel base material and the thermal expansion of the entire metal substrate is controlled by the thermal expansion properties of the base material and that the stress of the anodized film arising from the difference in thermal expansion between the base material and anodized film is alleviated by the interposition of the Al material having a small elastic modulus between the base material and anodized film.

### (Design Change Example of Insulating Layer Provided Metal Substrate)

FIG. 2 is a schematic cross-sectional view of another insulating layer provided metal substrate, illustrating a design change example. In the embodiment above, the description has been made of a case in which metal substrate 14 has a bimetal structure of base material 13 and Al material 11. The metal substrate, however, is not limited to the bimetal structure, and it may have a three-layer structure, from the viewpoint of corrosion resistance and anodizability, in which Al materials 11 and 11′ are provided on the respective surfaces of base material 13 as shown in FIG. 2. That is, insulating layer provided metal substrate 10′ shown in FIG. 2 includes metal substrate 14′ of steel base material 13 with Al materials 11 and 11′ integrated to respective surfaces of base material 13, and porous Al anodized films 12 and 12′ formed on the respective surfaces of Al materials 11 and 11′, as electrical insulating layers, by anodizing the surfaces of Al materials 11 and 11′.

In metal substrate 14′ having a three-layer structure of Al material 11′, base material 13, and Al material 11, only either one of Al materials 11 and 11′ may be anodized to provide an insulating layer provided metal substrate having a structure in which an anodized film is provided on the surface of only either one of Al materials. Further, in metal substrate 14′, Al material 11 and Al material 11′ may be made of the same raw material or different raw materials. That is, the surface of a metal substrate on which a photoelectric circuit is not provided may take any form which is suitable for manufacturing in view of surface hardness, corrosion resistance, deformation at high temperatures, and the like.

Here, when anodizing metal substrate 14′ having the three-layer structure, it is necessary to mask/insulate the end face if both surfaces are anodized and if only one surface is anodized, it is necessary to mask/insulate the end face and the other surface in order to prevent the formation of a local battery between steel base material 13 and Al materials 11 and 11′,

The insulating layer provided metal substrate may have a three-layer structure of metal substrate 14′ with anodized films 12 and 12′ provided on the respective surfaces thereof as shown in FIG. 2 because the substrate may curl due to thermal strain when heated to a high temperature in a film forming process of photoelectric conversion layer of a compound semiconductor.

### (Configuration of Solar Cell Device)

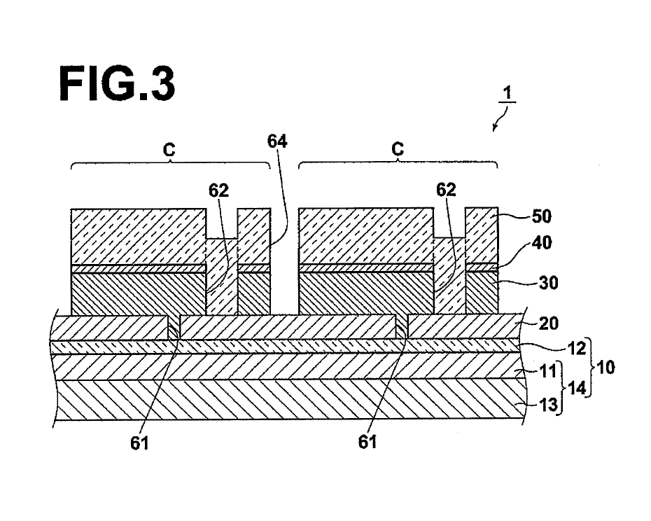

Hereinafter, a solar cell device of the present invention having a photoelectric conversion circuit on the aforementioned insulating layer provided metal substrate will be described. First, an overall configuration of the solar cell device will be described with reference to FIG. 3. The solar cell device of the present embodiment is a cell having a photoelectric conversion layer of a compound semiconductor, in which multiple photoelectric conversion element structures are connected in series to provide a high voltage output. FIG. 3 is a schematic cross-sectional view of a major portion of the solar cell device.

Solar cell device 1 is a cell having insulating layer provided metal substrate 10 shown in FIG. 1 with lower electrode 20, photoelectric conversion semiconductor layer 30 of a compound semiconductor, buffer layer 40, and upper electrode (transparent electrode) 50 being stacked in this order on anodized film 12 provided on the surface of substrate 10.

Solar cell device 1 has grooves 61 that run through only lower electrode 20, grooves 62 that run through photoelectric conversion layer 30 and buffer layer 40, and grooves 64 that run through photoelectric conversion layer 30, buffer layer 40, and upper electrode layer 50.

The above configuration may provide a structure of many cells C divided by grooves 64. Further, upper electrode 50 is filled in grooves 62, whereby a structure in which upper electrode 50 of a certain cell C is serially connected to lower electrode 20 of adjacent cell C may be obtained. It is preferable that an electrode having a highest potential when the solar cell device is driven among the serially connected elements (positive electrode on the most positive side) is electrically connected (short-circuited) to metal substrate for increasing the insulating performance of the anodized layer (Japanese Patent Application No. 2009-093536, not yet laid open at the time of filing the present application). Generally, the lower electrode is used as the positive electrode and therefore the lower electrode is short-circuited to the metal substrate.

### (Photoelectric Conversion Layer)

Photoelectric conversion layer 30 is a layer that generates a charge by absorbing light and is formed of a compound semiconductor. Photoelectric conversion layer 30 is formed on an insulating layer provided metal substrate via a lower electrode under a substrate temperature of not less than 500° C. Film formation at 500° C. or higher may provide a photoelectric conversion layer having favorable light absorption and photoelectric conversion characteristics. There is not any specific restriction on the major component of photoelectric conversion layer 30, but is preferable to be at least one type of compound semiconductor having a chalcopyrite structure. Here, it is preferable that the compound semiconductor is at least one type of compound semiconductor formed of a group Ib element, a group IIIb element, and a group VIb element. As having a high light absorption rate and providing high photoelectric conversion efficiency, the group Ib element is at least one type of element selected from the group consisting of Cu and Ag, the group IIIb element is at least one type of element selected from the group consisting of Al, Ga, and In, and the group VIb element is at least one type of element selected from the group consisting of S, Se, and Te.

Specific examples of such compound semiconductors include CuAlS₂, CuGaS₂, CuInS₂, CuAlSe₂, CuGaSe₂, CuInSe₂ (CIS), AgAlS₂, AgGaS₂, AgInS₂, AgAlSe₂, AgGaSe₂, AgInSe₂, AgAlTe₂, AgGaTe₂, AgInTe₂, Cu(In₁₋ₓGaₓ)Se₂ (CIGS), Cu(In₁₋ₓAlₓ)Se₂, Cu(In₁₋ₓGaₓ)(S,Se)₂, Ag(In₁₋ₓGaₓ)Se₂, Ag(In₁₋ₓGaₓ)(S,Se)₂, and the like.

It is particularly preferable that photoelectric conversion layer 30 includes CuInSe₂ (CIS) and/or a compound thereof solidified with Ga, i.e, Cu(In,Ga)S₂ (CIGS). CIS and CIGS are semiconductors having a chalcopyrite crystal structure and a high light absorption rate and high energy conversion efficiency thereof are reported. Further, they are excellent in the durability with less deterioration in the conversion efficiency due to light exposure and the like.

Photoelectric conversion layer 30 includes an impurity for obtaining an intended semiconductor conductivity type. The impurity may be included in photoelectric conversion layer 30 by diffusing from an adjacent layer and/or by active doping. Photoelectric conversion layer 30 may have a concentration distribution of constituent elements of group I-III-VI semiconductor and/or an impurity, and may have a plurality of layer regions of different semi-conductivities, such as n-type, p-type, i-type, and the like. For example, in a CIGS system, if Ga content of photoelectric conversion layer 30 is distributed in the thickness direction, bandgap width/carrier mobility and the like can be controlled, whereby a higher photoelectric conversion efficiency value can be designed. Photoelectric conversion layer 30 may include one or more types of semiconductors other than the group I-III-VI semiconductor. Semiconductors other than the group I-III-VI semiconductor may include a semiconductor of group IVb element, such as Si (group IV semiconductor), a semiconductor of group IIIb element and group Vb element such as GaAs (group III-V semiconductor), and a semiconductor of group IIb element and group VIb element, such as CdTe (group II-VI semiconductor). Photoelectric conversion layer 30 may include any arbitrary component other than semiconductors and an impurity for causing the semiconductors to become an intended conductivity type within a limit that does not affect the properties. There is not any specific restriction on the content of group I-III-VI semiconductor in photoelectric conversion layer 30, which is preferable to be not less than 75% by mass, more preferably not less than 95% by mass, and particularly preferably not less than 99% by mass.

As for the method of forming a CIGS layer, 1) multi-source simultaneous deposition (J. R. Tuttle et al., “The Performance of Cu(In,Ga)Se₂-Based Solar Cells in Conventional and Concentrator Applications”, Material Research Society (MRS) Symposium Proceedings, Vol. 426, pp. 143-151, 1996, and H. Miyazaki et al., “Growth of high-quality CuGaSe₂ thin films using ionized Ga precursor”, Physica status solidi (a), Vol. 203, No. 11, pp. 2603-2608, 2006, and the like), 2) selenization (T. Nakada et al., “CuInSe₂-based solar cells by Se-vapor selenization from Se-containing precursors”, Solar Energy Materials and Solar Cells, Vol. 35, pp. 209-214, 1994, and T. Nakada et al., “THIN FILMS OF CuInSe₂ PRODUCED BY THERMAL ANNEALING OF MULTILAYERS WITH ULTRA-THIN STACKED ELEMENTAL LAYERS”, Proceedings of the 10th European Photovoltaic Solar Energy Conference (EU PVSEC), pp. 887-890, 1991, and the like), 3) sputtering (J. H. Ermer et al., “CdS/CuInSe₂ JUNCTIONS FABRICATED BY DC MAGNETRON SPUTTERING OF Cu₂Se AND In₂Se₃”, Proceedings of the 18th IEEE Photovoltaic Specialists Conference, pp. 1655-1658, 1985, and T. Nakada et al., “Polycrystalline CuInSe₂ Thin Films for Solar Cells by Three-Source Magnetron Sputtering”, Japanese Journal of Applied Physics, Vol. 32, Part 2, No. 8B, pp. L1169-L1172, 1993, and the like), 4) hybrid sputtering (T. Nakada et al., “Microstructural Characterization for Sputter-Deposited CuInSe₂ Films and Photovoltaic Devices”, Japanese Journal of Applied Physics, Vol. 34, Part 1, No. 9A, pp. 4715-4721, 1995, and the like), 5) mechano-chemical process (T. Wada et al., “Fabrication of Cu(In,Ga)Se₂ thin films by a combination of mechanochemical and screen-printing/sintering processes”, Physica status solidi (a), Vol. 203, No. 11, pp. 2593-2597, 2006, and the like), and the like are known. Other CIGS film forming methods include screen printing, proximity sublimation, MOCVD, spraying, and the like. For example, a crystal having a desired composition may be obtained by forming a particle film that includes a group Ib element, a group IIIb element, and a group VIb element on a substrate and performing pyrolytic processing (which may be performed under the group VIb element atmosphere) on the particle film (Japanese Unexamined Patent Publication Nos. 9(1997)-074065 and 9(1997)-074213, and the like).

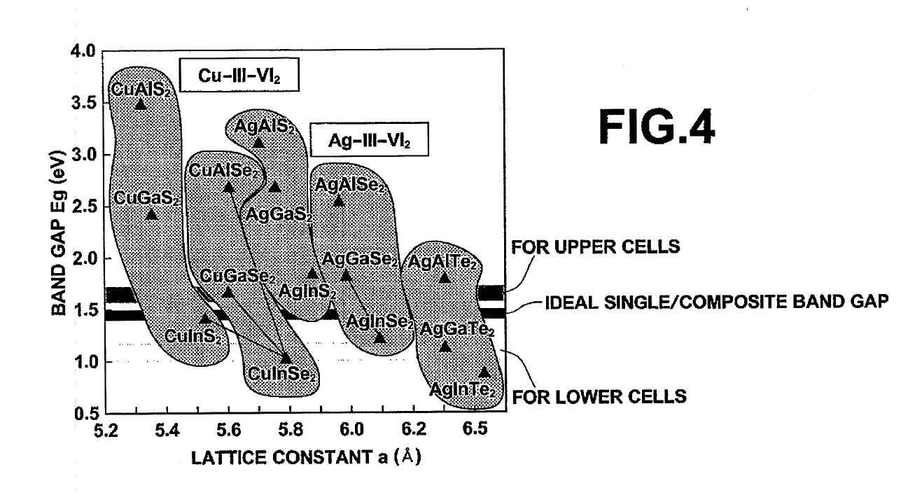

FIG. 4 illustrates the relationship between the lattice constant and bandgap of major I-III-VI compound semiconductors. FIG. 4 shows that various bandgaps may be obtained by changing the composition ratio. When a photon having a greater energy than the bandgap is incident on a semiconductor, the amount of energy exceeding the bandgap becomes heat loss. It has been known by a theoretical calculation that the conversion efficiency becomes maximal at about 1.4 to 1.5 eV in the combination between solar spectrum and bandgap. For example, Ga concentration in Cu(In,Ga)Se₂ (CIGS), Al concentration in Cu(In, Al)Se₂, or S concentration in Cu(In,Ga)(S,Se)₂ may be increased to increase the bandgap in order to increase the photoelectric conversion efficiency, whereby a high conversion efficiency bandgap may be obtained. In the case of CIGS, the bandgap may be adjusted in the range from 1.04 to 1.68 eV.

The band structure may be graded by varying the composition ratio in the film thickness direction. Two types of graded structures are known, one of which is a single graded bandgap in which the bandgap increases from the light entrance window side toward the electrode side on the opposite and the other of which is a double graded bandbap in which the bandgap decreases from the light entrance window side toward the PN junction and increases after passing the PN junction (“A new approach to high-efficiency solar cells by band gap grading in Cu(In,Ga)Se₂ chalcopyrite semiconductors”, T. Dullweber et al., Solar Energy Materials and Solar Cells, Vol. 67, pp. 145-150, 2001, and the like). In either case, carriers induced by light are more likely to reach the electrode due to acceleration by an electric field generated inside thereof by the gradient of the band structure, whereby the probability of recombination in the recombination center is reduced and the photoelectric conversion efficiency is increased (International Patent Publication No. WO2004/090995, and the like).

The major component of photoelectric conversion layer 30 may be CdTe which is a group II-VI semiconductor. The photoelectric conversion layer of CdTe may be formed by a proximity sublimation method on a metal or graphite lower electrode provided on an Al anodized film. The proximity sublimation method is a method in which a CdTe material is heated to about 600° C. in a vacuum and CdTe crystals are condensed on a substrate maintained at a temperature lower than that of the CdTe material.

### (Electrodes and Buffer Layer)

Each of lower electrode (rear electrode) 20 and upper electrode (transparent electrode) 50 is made of a conductive material. Upper electrode 50 on the light input side needs to be transparent.

For example, Mo may be used as the material of lower electrode 20. Preferably, the thickness of lower electrode 20 is not less than 100 nm, and more preferably in the range from 0.45 to 1.0 μm. There is not any specific restriction on the film forming method of lower electrode 20, and a vapor phase film forming method, such as an electron beam deposition method or a sputtering method may be preferably used. Preferably, the major component of upper electrode 50 is ZnO, ITO (indium tin oxide), SnO₂, or a combination thereof. Upper electrode 50 may have a single layer structure or a laminated structure, such as a two-layer structure. There is not any specific restriction on the thickness of upper electrode 50 and a value of 0.6 to 1.0 μm is preferably used. As for buffer layer 40, CdS, ZnS, ZnO, ZnMgO, ZnS(O,OH), or a combination thereof is preferably used.

A preferable combination of the compositions is, for example, a Mo lower electrode, a CdS buffer layer, a CIGS photoelectric conversion layer, and a ZnO upper electrode.

It is reported that, in a photoelectric conversion device using a soda lime glass substrate, an alkali metal element (Na element) in the substrate is diffused into the CIGS film, thereby improving energy conversion efficiency. In the present embodiment, it is also preferable to diffuse an alkali metal into the photoelectric conversion layer of CIGS and the like. As for the alkali metal diffusion method, a method in which a layer including an alkali metal element is formed on a Mo lower electrode by deposition or sputtering as described, for example, in Japanese Unexamined Patent Publication No. 8(1996)-222750, a method in which an alkali layer of Na₂S or the like is formed on a Mo lower electrode by soaking process as described, for example, in International Patent Publication No. WO03/069684, a method in which a precursor of In, Cu, and Ga metal elements is formed on a Mo lower electrode and then, for example, an aqueous solution including sodium molybdate is deposited on the precursor, or the like may be cited.

It is also preferable to form a layer of one or more types of alkali metal compounds, such as Na₂S, Na₂Se, NaCl, NaF, and sodium molybdate salt, inside of lower electrode 20.

There is not any specific restriction on the conductivity type of photoelectric conversion layer 30, buffer layer 40, and upper electrode 50. Generally, photoelectric conversion layer 30 is a p-layer, buffer layer 40 is an n-layer (n-Cds, or the like), and upper electrode 50 is an n-layer (n-ZnO layer, or the like) or has a laminated structure of i-layer and n-layer (i-ZnO layer and n-ZnO, or the like). It is believed that such conductivity types form a p-n junction or a p-i-n junction between photoelectric conversion layer 30 and upper electrode 50. Further, it is thought that provision of CdS buffer layer 40 on photoelectric conversion layer 30 results in an n-layer to be formed in a surface layer of photoelectric conversion layer 30 by Cd diffusion, whereby a p-n junction is formed inside of photoelectric conversion layer 30. It is also conceivable that an i-layer may be provided below the n-layer inside of photoelectric conversion layer 30 to form a p-i-n junction inside of photoelectric conversion layer 30.

Solar cell device 1 may further include, as required, any layer other than those described above. For example, a close contact layer (buffer layer) may be provided, as required, between insulating layer provided metal substrate 10 and lower electrode 20 and/or between lower electrode 20 and photoelectric conversion layer 30 for enhancing the adhesion of the layers. Further, an alkali barrier layer may be provided between insulating layer provided metal substrate 10 and lower electrode 20 for preventing diffusion of alkali ions. For details of alkali barrier layer, refer to Japanese Unexamined Patent Publication No. 8(1996)-222750.

Further, a cover glass, a protection film, and the like may be attached, as required, to solar cell device 1.

As described above, the solar cell device of the present invention includes insulating layer provided metal substrate 10 as the substrate. Insulating layer provided metal substrate 10 may prevent crack generation in the anodized film even when subjected to a high temperature (500° C. or higher) in a semiconductor film forming process and maintain high insulating properties. That is, insulating layer provided metal substrate 10 is a high temperature resistive substrate and allows a compound semiconductor layer to be formed at a temperature not less than 500° C., whereby the solar cell device may have high photoelectric conversion characteristics. Further, substrate 10 includes a base material capable of maintaining a high rigidity even in the environment of high temperature, so that handling constraints and the like during the manufacturing may be reduced.

The insulating layer provided metal substrate used for the solar cell device of the present invention may also be used as a substrate of a wide variety of semiconductor devices other than solar cell applications. More specifically, for example, it may be applied to a flexible transistor or the like.

### EXAMPLES

Examples 1 to 5 of insulating layer provided metal substrate used for the solar cell device of the present invention and Comparative Examples 1 to 3 will now be described.

### Example 1

A commercially available austenitic stainless steel (Quality: SUS304 (JIS Standards)) and high purity (4N) aluminum were bonded together by a cold rolling method and reduced in the thickness to provide a two-layer clad material of the stainless steel with a thickness of 100 μm and Al with a thickness of 30 μm and used as a metal substrate. The stainless steel surface and end face of the metal substrate were masked by a masking film and subjected to ultrasonic cleaning with ethanol, electropolishing in a solution of acetic acid and perchloric acid, and constant-voltage electrolysis with 40 V in a solution of 80 g L oxalic acid, whereby a porous anodized film was formed, as an insulating layer, on Al surface with a thickness of 10 μm. The thickness of Al after the anodization was 5 μm. Through the processes described above, an insulating layer provided metal substrate having a structure of the anodized film (10 μm)/Al (5 μm)/stainless steel (100 μm) was obtained.

### Example 2

A commercially available Al/steel/Al plate (with respective thicknesses of 20/110/20 μm, Al quality: equivalent of JIS1200 (JIS Standards), steel: SPCC low carbon steel (JIS Standards)) produced by a cold rolling method was used as a metal substrate. After the end face of the metal substrate was masked with a masking film, the substrate was cleaned, polished, and anodized through a procedure identical to that of Example 1, whereby a porous anodized film was formed, as an insulating layer, on each surface of Al with a thickness of 10 μm. The thickness of Al after the anodization was 5 μm. Through the processes described above, an insulating layer provided metal substrate having a structure of the anodized film (10 μm)/Al (5 μm)/stainless steel (110 μm)/Al (5 μm)/anodized film (10 μm) was obtained.

### Example 3

A commercially available ferritic stainless steel (quality: SUS 430) and high purity Al (purity: 4N) were pressure bonded together by a cold rolling method and the thickness thereof was reduced to provide a metal substrate of two-layer clad material of 50 μm thick stainless and 30 μm thick Al. The metal substrate was masked with a masking film, cleaned, polished, and anodized through a procedure identical to that of Example 1, whereby a porous anodized film was formed on the Al surface. The thickness of Al after the anodization was 15 μm. Through the processes described above, an insulating layer provided metal substrate having a structure of the anodized film (10 μm)/Al (15 μm)/stainless steel (50 μm) was obtained.

### Example 4

A metal substrate identical to that of Example 3 was used and a porous anodized film was formed through a procedure identical to that of Example 3. Then, the substrate was subjected to constant-voltage electrolysis with 1 mA/cm² and 400 V in a ph 7.4 solution of 0.5M boric acid and 0.05M boric acid Na. That is, electrolysis in an acid solution was performed first, and then pore filling in which electrolysis is performed in a neutral electrolyte was performed. After the processing, the thickness of Al was 15 μm and a barrier layer at the interface between Al and porous anodized film was 0.5 μm. Through the processes described above, an insulating layer provided metal substrate having a structure of the anodized film (10 μm)/Al (15 μm)/stainless steel (50 μm) was obtained.

### Example 5

Commercially available pure Ti (purity: 99.5%) and high purity Al (purity: 4N) were pressure bonded together by a cold rolling method and the thickness thereof was reduced to provide a metal substrate of two-layer clad material of 80 μm thick Ti and 15 μm thick Al. The metal substrate was masked with a masking film, cleaned, polished, and anodized through a procedure identical to that of Example 1, whereby a porous anodized film was formed on the Al surface. The thickness of Al after the anodization was 5. Through the processes described above, an insulating layer provided metal substrate having a structure of the anodized film (10 μm)/Al (5 μm)/Ti (80 μm) was obtained.

### Comparative Example 1

Commercial available high purity Al (thickness: 500 μm, quality: 4N purity grade, rolled finish) was cleaned, polished, and anodized through a procedure identical to that of Example 1 without using a masking film to form a porous anodized film on each surface of Al with a thickness of 10 μm. Through the processes described above, an insulating layer provided metal substrate having a structure of the anodized film (10 μm)/Al (450 μm)/anodized film (10 μm) was obtained.

### Comparative Example 2

Commercial available Al (thickness: 300 μm, quality: JIS1200 grade (JIS Standards), rolled finish) was cleaned, polished, and anodized through a procedure identical to that of Example 1 without using a masking film to form a porous anodized film on each surface of Al with a thickness of 10 μm. Through the processes described above, an insulating layer provided metal substrate having a structure of the anodized film (10 μm)/Al (250 μm)/anodized film (10 μm) was obtained.

### Comparative Example 3

A metal substrate identical to that of Example 3 was subjected to constant-voltage/constant-current electrolysis with 1 mA/cm² and 600 V in a ph 7.4 solution of 0.5M boric acid and 0.05M boric acid Na to form a porous and dense barrier type anodized film on the Al surface. After the anodization, the thickness of Al was 28 μm and the thickness of dense anodized film was 0.8 μm. Through the processes described above, an insulating layer provided metal substrate having a structure of the non-porous and dense anodized film (10 μm)/Al (250 μm)/stainless steel (50 μm) was obtained.

### Comparative Example 4

A ferritic stainless steel (SUS 430, thickness: 100 μm) identical to that of Example 3 was used as the base material, and the base material was dipped in molten high purity (4N) aluminum at a temperature of 700° C. to obtain a metal substrate of SUS 430 with each surface thereof plated with molten high purity aluminum. An alloy layer of Al, Cr, and Fe was formed at the interface between the SUS 430 and high purity Al with a thickness of about 15 μm. The metal substrate was masked with a masking film, cleaned, polished, and anodized through a procedure identical to that of Example 2, whereby a porous anodized film was formed on the Al surface. The thickness of Al after the anodization was 15 μm, and the thickness of the alloy layer formed at the interface between the SUS 430 and Al remained at 15 μm. Through the processes described above, an insulating layer provided metal substrate having a structure of the anodized film (10 μm)/Al (15 μm)/alloy layer (15 μm)/stainless steel (100 μm)/alloy layer/Al/anodized layer was obtained.

### Comparative Example 5

A ferritic stainless steel (SUS 430, thickness: 100 μm) identical to that of Example 3 was used as the base material, and the base material was dipped in an molten alloy (melting point of 570° C.) of 55 wt % of Al, 43.4 wt % of Zn, 1.6 wt % of Si at a temperature of 600° C. to obtain a metal substrate of SUS 430 with each surface thereof molten plated with an Al alloy having substantially the identical composition. An alloy layer of Al, Cr, Fe, and Zn was formed at the interface between the SUS 430 and the Al alloy with a thickness of about 3 μm. The metal substrate was masked with a masking film, cleaned, polished, and anodized through a procedure identical to that of Example 2, whereby a porous anodized film was formed on the Al surface. The thickness of Al after the anodization was 15 μm, and the thickness of the alloy layer formed at the interface between the SUS 430 and Al remained at 3 μm. Through the processes described above, an insulating layer provided metal substrate having a structure of the anodized film (10 μm)/Al (15 μm)/alloy layer (3 μm)/stainless steel (100 μm)/alloy layer/Al/anodized layer was obtained.

### Comparative Example 6

A ferritic stainless steel (SUS 430, thickness: 100 μm) identical to that of Example 3 was used as the base material, and the base material was dipped in an molten alloy (melting point of 550° C.) of 80 wt % of Al and 20 wt % of Mg at a temperature of 600° C. to obtain a metal substrate of SUS 430 with each surface thereof molten plated with an Al alloy having substantially the identical composition. An alloy layer of Al, Cr, Fe, and Mg was formed at the interface between the SUS 430 and the Al alloy with a thickness of about 5 μm. The metal substrate was masked with a masking film, cleaned, polished, and anodized through a procedure identical to that of Example 2, whereby a porous anodized film was formed on the Al surface. The thickness of Al after the anodization was 15 μm, and the thickness of the alloy layer formed at the interface between the SUS 430 and Al remained at 5 μm. Through the processes described above, an insulating layer provided metal substrate having a structure of the anodized film (10 μm)/Al (15 μm)/alloy layer (5 μm)/stainless steel (100 μm)/alloy layer/Al/anodized layer was obtained.

In each example and comparative example, the thickness of each of the anodized layer, Al, alloy layer, and the like was measured in the following manner. First, the metal substrate was cut with a diamond cutter, then the cut surface was smoothed by ion polishing using Al ion beam, and a reflected electron beam was obtained by a SEM-EDX (scanning electron microscope with an energy dispersive X-ray analyzer). The insulating layer (anodized film), Al layer, alloy layer, and base material layer have average atomic weights different from each other, so that an image with clear contrast can be obtained. The thickness of each layer was obtained by measuring the area of each layer in the image by image analysis and dividing the area by the length of the field of view.

### (Insulating Property Evaluation)

With respect to the insulating layer provided metal substrate obtained in each example and comparative example, insulating properties were compared between the state as it is (non-heated state) and the state after heated in a vacuum furnace at 500° C. for one hour. As the insulating property measurement, 0.2 μm Au is provided, as an electrode, on the anodized surface by shadow mask deposition with a diameter of 3.5 mmΦ. Then a voltage of 200 V was applied between the metal substrate and Au electrode with the Au electrode set to the negative polarity and leakage current flowing, when the voltage was applied, between the metal substrate and Au electrode was measured. Here, a leakage current density was calculated by dividing an amount of detected leakage current with the area of the Au electrode (9.6 mm²).

Table 1 summarizes the results of insulating property measurement of each substrate. Table 1 shows that, whereas the amount of leakage current in each comparative example increases significantly or the insulation is broken down after having thermal history of 500° C., the amount of leakage current in each example remains almost unchanged. This demonstrates that a solar cell device of the present invention using the substrate of each example can maintain favorable insulating properties and strength even after subjected to a thermal history of 500° C.×one hour. Further, if the metal substrate is formed by pressuring bonding the base material and Al material, as in Examples, the substrate has smaller amounts of leakage current both in the non-heated state and post-heated state. Further, Example 4, which was subjected to electrolysis in an acid electrolyte and further in a neutral electrolyte in the anodizing process, has an amount of leakage current which is one digit smaller in comparison with that of Example 3, which was subjected to electrolysis only in an acid electrolyte, showing high insulating performance.

Further, as in Comparative Example 3, non-porous and dense anodized film showed a very high insulation resistance in non-heat-treated state, but dielectric breakdown occurred when heated to a high temperature of 500° C. This demonstrates that a porous anodized film has a high resistance to crack generation due to difference in thermal expansion at a high temperature in comparison with a non-porous and dense anodized film.

Comparative Example 4 showed favorable insulation properties in non-heat-treated state, but dielectric breakdown occurred when heated to a high temperature of 500° C. With respect to Comparative Example 5, dielectric breakdown occurred even in non-heat-treated state by a voltage of 200 V. Further, Comparative Example 6 showed high leakage current even in non-heat-treated state and dielectric breakdown occurred after heated to 500° C. In each of Comparative Examples 4 to 6, a sample heated to 500° C., in comparison with a sample not heated, showed growth of an alloy layer of about 5 μm and lessening of the Al layer. Further, a crack-like void was found between the Al and alloy layer and a crack was found in the anodized layer in the film thickness direction. Thus, it can be said that the dielectric breakdown is attributed to the crack developed in the anodized layer due to the growth of the alloy layer at the interface between the base material and Al material caused by a plurality of times of heating (heating at a temperature not less than 600° C. in molten plating and heating at 500° C. for one hour in the insulating property evaluation test). This clearly shows that a metal layer having an Al layer plated by molten plating can not provide sufficient insulating properties required of a modular solar cell device. Further, as in Comparative Examples 5 and 6, it has become clear that, if the plating material includes a large amount of component other than Al, the anodized film can not provide sufficient insulating properties.

TABLE 1

| | Non-Heated | Heated, 500° C./1 h |
|---|---|---|
| | Current Den'ty | Current Den'ty |
| | (μA/cm²) | (μA/cm²) |
| Example 1 | 0.71 | 1.3 |
| Example 2 | 7.6 | 9.1 |
| Example 3 | 0.70 | 0.70 |
| Example 4 | 0.062 | 0.061 |
| Example 5 | 0.68 | 0.67 |
| Comp. Example 1 | 0.52 | 61 |
| Comp. Example 2 | 7.0 | 73 |
| Comp. Example 3 | 0.095 | Dielectric Breakdown |
| Comp. Example 4 | 0.85 | Dielectric Breakdown |
| Comp. Example 5 | Dielectric Breakdown | Dielectric Breakdown |
| Comp. Example 6 | 32 | Dielectric Breakdown |

(Semiconductor Layer Surface Evaluation after Formed)

Next, a lower electrode and a semiconductor layer were formed on the insulating layer provided metal substrate in each of Examples 1 to 5 and Comparative Examples 1 to 3 to provide Examples 1-1 to 5-3, and Comparative Examples 1-1 to 3-1. Then, the semiconductor layer surface of each of these Examples and Comparative Examples was evaluated. The suffix 1—in Example 1—refers to that the example includes the insulating layer provided metal substrate in Example 1 on which a combination of lower electrode and semiconductor layer shown in Table 2, to be provided later, was formed. The same applies to Example 2-, Example 3-, and so on.

An Au or Mo lower electrode with a thickness of 0.5 μm was formed on the anodized film of the insulating film provided metal substrate in each of the examples and comparative examples by a sputtering method at room temperature. Then, a semiconductor layer was formed on the lower electrode with a substrate temperature of 500° C. As for the semiconductor layer, GaAs, CuIn_{0.7}Ga_{0.3}Se₂, or CdTe was formed. GaAs and CuIn_{0.7}Ga_{0.3}Se₂ were formed with a thickness of 2 μm by a vapor deposition method using K-Cell (Knudsen-Cell) as the deposition source. CdTe was formed with a thickness of 5 μm using a proximity sublimation method.

Table 2 summarizes the lower electrode, composition of semiconductor layer, difference in linear thermal expansion coefficient between the base material and semiconductor layer, and surface state evaluation of the semiconductor surface of each example. For Comparative Example 1, Table 2 shows the difference in linear thermal expansion coefficient between the Al material and semiconductor layer, since Comparative Example 1 has no other base material than Al. The evaluation was performed by observing the surface of each semiconductor layer after formed with an optical microscope and results were indicated by ∘, Δ, and x representing that no detachment or crack was found, a partial detachment or a crack was found, and a detachment of 1/10 or more of observation area was found respectively.

TABLE 2

| | | | Difference in | |
|---|---|---|---|---|
| | | | L.T.E. Coeffi. | |
| | | | between B/M and | Surf/State |
| | L/Electrode | S/Layer | S/Layer (/° C.) | Evaluation |
| Eg1-1 | Au | GaAs | 11.2 | Δ(partial |
| | | | | detachment |
| | | | | and crack) |
| Eg1-2 | Mo | GaAs | 11.2 | Δ(partial |
| | | | | detachment |
| | | | | and crack) |
| Eg1-3 | Au | CIGS | 7.0 | ∘ |
| Eg1-4 | Mo | CIGS | 7.0 | Δ(partial |
| | | | | detachment) |
| Eg1-5 | Au | CdTe | 12.5 | x |
| Eg1-6 | Mo | CdTe | 12.5 | x |
| Eg2-1 | Au | GaAs | 5.0 | ∘ |
| Eg2-2 | Mo | GaAs | 5.0 | ∘ |
| Eg2-3 | Au | CIGS | 0.8 | ∘ |
| Eg2-4 | Mo | CIGS | 0.8 | ∘ |
| Eg3-1 | Au | GaAs | 4.7 | ∘ |
| Eg3-2 | Mo | GaAs | 4.7 | ∘ |
| Eg3-3 | Au | CIGS | 0.5 | ∘ |
| Eg3-4 | Mo | CIGS | 0.5 | ∘ |
| Eg3-5 | Au | CdTe | 6.0 | ∘ |
| Eg3-6 | Mo | CdTe | 6.0 | ∘ |
| Eg4-1 | Mo | GaAs | 4.7 | ∘ |
| Eg4-2 | Mo | CIGS | 0.5 | ∘ |
| Eg4-3 | Mo | CdTe | 6.0 | ∘ |
| Eg5-1 | Au | CIGS | 0.8 | ∘ |
| Eg5-2 | Mo | CIGS | 0.8 | ∘ |
| Eg5-3 | Mo | CdTe | 4.7 | ∘ |
| C/Eg1-1 | Au | GaAs | 17.2 | x |
| C/Eg1-2 | Au | CIGS | 13.0 | x |
| C/Eg1-3 | Mo | CIGS | 13.0 | x |
| C/Eg1-4 | Au | CdTe | 18.5 | x |
| C/Eg2-1 | Au | CIGS | 13.0 | x |
| C/Eg3-1 | Au | CIGS | 0.5 | ∘ |

Any significant detachment was not found for the examples having a difference in linear thermal expansion coefficient between the base material and compound semiconductor not greater than 7×10⁻⁶/° C. at room temperature other than Example 1-4 in which a partial detachment was found. Examples and comparative examples having CIGS on Mo had MoSe₂ formed at the interface between Mo and CIGS with a thickness of about 30 nm. It is presumed that the generation of MoSe₂ might be the cause of the partial detachment in Example 1-4 even the difference in thermal expansion coefficient is 7 ppm/° C. In the mean time, those having a difference in thermal expansion coefficient between the base material and semiconductor less than 7 ppm/° C., as Examples 2 to 5, had no film forming defect, such as detachment or crack, even though MoSe₂ was generated.

1. A solar cell device having a photoelectric conversion layer of a compound semiconductor, the solar cell device comprising:
an insulating layer provided metal substrate constituted by a metal substrate and a porous Al anodized film, the metal substrate being formed of a base material of a metal having a higher rigidity, a higher heat resistance, and a smaller linear thermal expansion coefficient than Al and an Al material integrated by pressure bonding to at least one surface of the base material, and the porous Al anodized film being formed, as an electrical insulating layer, on a surface of the Al material of the metal substrate; and
a photoelectric conversion circuit, which includes the photoelectric conversion layer, and upper and lower electrodes disposed respectively on the upper and lower sides of the photoelectric conversion layer, formed on the insulating layer provided metal substrate.

2. The solar cell device of claim 1, wherein the metal of the base material is a steel material or a Ti material.

3. The solar cell device of claim 1, wherein the photoelectric conversion circuit is a circuit formed of a plurality of elements provided by dividing the photoelectric conversion layer by a plurality of grooves and electrically connected in series.

4. The solar cell device of claim 1, wherein the difference in linear thermal expansion coefficient between the base material and the photoelectric conversion layer is less than 7×10-6/° C.

5. The solar cell device of claim 1, wherein the major component of the photoelectric conversion layer is at least one type of compound semiconductor having a chalcopyrite structure.

6. The solar cell device of claim 5, wherein:
the base material is a carbon steel material, a ferritic stainless steel material, or the Ti material;
the lower electrode is formed of Mo; and
the major component of the photoelectric conversion layer is at least one type of compound semiconductor formed of a group Ib element, a group Mb element, and a group VIb element.

7. The solar cell device of claim 6, wherein:
the group Ib element is at least one type of element selected from the group consisting of Cu and Ag;
the group Mb element is at least one type of element selected from the group consisting of Al, Ga, and In; and
the group VIb element is at least one type of element selected from the group consisting of S, Se, and Te.

8. The solar cell device of claim 1, wherein:
the base material is a carbon steel material, a ferritic stainless steel material, or the Ti material; and
the major component of the photoelectric conversion layer is a CdTe compound semiconductor.

9. A method of manufacturing a solar cell device, comprising the steps of:
providing an insulating layer provided metal substrate constituted by a metal substrate and a porous Al anodized film, the metal substrate being formed of a base material of a metal having a higher rigidity, a high heat resistance, and a smaller linear thermal expansion coefficient than Al and an Al material integrated by pressure bonding to at least one surface of the base material, and the porous Al anodized film being formed, as an electrical insulating layer, on a surface of the Al material of the metal substrate; and
forming a photoelectric conversion layer of a compound semiconductor on the insulating layer provided metal substrate at a film forming temperature of not less than 500° C.
